(19) United States
(12) Patent Application Publication
(10) Pub. No.: US 2026/0086233 A1
(43) Pub. Date: Mar. 26, 2026

(54) THROUGH-DISPLAY PROXIMITY SENSORS WITH REDUCED TEMPERATURE DEPENDENCE

(71) Applicant: Apple Inc., Cupertino, CA (US)

(72) Inventors: Tong Chen, Fremont, CA (US); Wenrui Cai, San Jose, CA (US); Clint M. Perlaki, San Jose, CA (US); James J. Dudley, Sunnyvale, CA (US); Xiao Xiang, San Jose, CA (US)

(21) Appl. No.: 19/326,487

(22) Filed: Sep. 11, 2025

Related U.S. Application Data
(60) Provisional application No. 63/698,451, filed on Sep. 24, 2024.

(51) Int. Cl. G01S 17/36; G01S 7/481; G01S 7/4911; G01S 7/497; G01S 17/04; G01S 17/88; G06F 3/03; H01S 5/183

(52) U.S. Cl. CPC G01S 17/36; G01S 7/4813; G01S 7/4815; G01S 7/4911; G01S 17/04; G01S 17/88; G06F 3/0308; H01S 5/18355; G01S 7/497

(57) ABSTRACT

An optical sensing systems for through-display sensing. The optical sensing system includes a transmit side and a receive side. The transmit side includes at least two polarization-locked laser elements that are oriented to emit polarized light in two separate orientations orthogonal to one another through an inter-pixel region of the display. The different polarizations decrease temperature dependence of crosstalk magnitude.

### CROSS REFERENCE TO RELATED APPLICATION

This application is a nonprovisional of and claims the benefit under 35 U.S.C. § 119 (e) of U.S. Provisional Patent Application No. 63/698,451, filed on Sep. 24, 2024, the contents of which are incorporated herein by reference as if fully disclosed herein.

### TECHNICAL FIELD

Embodiments described herein relate to proximity sensing systems for portable electronic devices and, in particular, to optical transceiver systems for proximity sensing through an electronic device display with reduced temperature dependence.

### BACKGROUND

An electronic device can include a proximity sensor. Typically, a proximity sensor emits infrared light and monitors for reflections of that light to determine whether an object, such as a user, is within a threshold distance of the electronic device. In conventional constructions, a portion of light emitted by the proximity sensor is reflected by layers of the electronic device itself (e.g., cover glass, housing layers, and so on), causing interference with the signal, typically referred to as “crosstalk.” In addition, as a user grips the device and/or transports it from place to place, temperature(s) of the proximity sensor can rapidly change, causing interference referred to as “signal drift.” Signal drift and/or crosstalk can also be caused by self-heating or self-cooling of a proximity sensor when in operation.

Signal drift and crosstalk substantially reduce both accuracy and precision of conventional proximity sensors, often causing an electronic device leveraging such sensors to exhibit behavior(s) such as: enabling or disabling a capacitive touch screen at unexpected times; dimming or brightening a display at unexpected times; increasing or decreasing speaker volume at unexpected times; and so on.

### SUMMARY

Embodiments described herein relate to optical sensing systems for through-display sensing. An optical sensing system includes a transmit side and a receive side. The transmit side includes at least two polarization-locked vertical cavity surface emitting laser (VCSEL) elements that are oriented on the same die or different dies to emit light polarized in two separate orientations orthogonal to one another.

In another non-limiting example, a first polarization-locked VCSEL is configured to emit light in a first orientation and a second polarization-locked VCSEL is configured to emit light in a second orientation that is orthogonal to the first orientation. The transmit side can be positioned behind a display of an electronic device, and may be configured to emit the two polarizations of light through inter-pixels regions of the display.

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIG. 1 depicts an electronic device incorporating an optical sensing system to detect proximity of an object, such as described herein.

FIG. 2 depicts a simplified schematic cross-section view, taken through line 2-2, of the optical sensing system of FIG. 1.

FIG. 3 depicts another cross-section view of an optical sensing system, such as described herein.

FIG. 4A depicts a pair of polarization-locked laser elements formed on two separate orthogonally-oriented dies, as described herein.

FIG. 4B depicts a pair of polarization-locked laser elements formed on a common die, as described herein.

FIG. 5 depicts a system diagram of an optical sensing system, such as described herein.

FIG. 6 is a flowchart depicting example operations of a method of operating an optical sensing system, such as described herein.

The use of the same or similar reference numerals in different figures indicates similar, related, or identical items.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Certain accompanying figures include vectors, rays, traces, and/or other visual representations of one or more example paths—which may include reflections, refractions, diffractions, and so on, through one or more media—that may be taken by, or may be presented to represent, one or more photons, wavelets, or other propagating electromagnetic energy originating from, or generated by, one or more light sources shown or, or in some cases, omitted from, the accompanying figures. It is understood that these simplified visual representations of light or, more generally, electromagnetic energy, regardless of spectrum (e.g., ultraviolet, visible light, infrared, and so on), are provided merely to facilitate an understanding of the various embodiments described herein and, accordingly, may not necessarily be presented or illustrated to scale or with angular precision or accuracy, and, as such, are not intended to indicate any preference or requirement for an illustrated embodiment to receive, emit, reflect, refract, focus, and/or diffract light at any particular illustrated angle, orientation, polarization, color, or direction, to the exclusion of other embodiments described or referenced herein.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments described herein relate to an optical proximity sensing system configured to be disposed below a display stack of an electronic device. The optical sensing system includes a transmitter side and a receiver side. The transmitter side is defined at least in part by a light emitting element and the receiver side is defined at least in part by a photodiode.

The transmitter side and the receiver side can be positioned adjacent to one another, and may be separated by an optical boundary. The light emitting element can have an emission surface from which light is emitted and the photodiode can include a photosensitive surface upon which light may be incident electronically detected.

The emission surface and the photosensitive surface may be coplanar or otherwise generally parallel to each other, separated by the optical boundary at a given distance. As a result of this architecture, light may be emitted from the light emitting element, propagate away from the optical sensing system into free space (e.g., air), illuminate an object some distance from the optical sensing system, and reflect—at least partially—back toward the photodiode.

A portion of the reflected light may become incident upon the photosensitive surface, inducing an electrical signal (or modifying an electrical signal or property) in a measurable way. The photodiode can be conductively coupled to one or more circuits, amplifiers, filters, and/or digital or analog processing pipelines that cooperate to generate an electrical signal or digital value (collectively “output” of the optical sensing system) that deterministically corresponds to or more properties of the object that caused the reflection.

In one example, an output of the optical sensing system may be a binary indication of presence of the object. In another example, an output of the optical sensing system may be a distance measurement to the object. In another example, an output may be a velocity of the object, which may be a radial velocity or a path velocity. In still further examples, an output of the optical sensing system may be a value that corresponds to a quantization of distance to the object into one or more predefined distance quanta (e.g., touching, nearby, close, distant, or the like). In other examples, output of the optical sensing system can correspond to a surface feature or property of the object. For example, if the object a biological subject, output of the optical sensor may correspond to a biological or biometric property of that subject (e.g., heart rate, respiration rate, and so on).

The foregoing examples are not exhaustive; an optical sensing system as described herein can be configured in a number of suitable ways and may be configured to provide as output a number of analog or digital values that correspond to one or more properties of an object in free space.

For simplicity of illustration and description, many embodiments described herein reference an optical sensing system configured as a proximity sensor providing at least binary output (but may provide quantized or distance measurements as output) indicating presence or absence of an object in free space. It may be appreciated that this is merely one example construction and that other embodiments may be implemented differently.

As noted above, an optical sensing system as described herein is typically configured to be positioned behind a display of an electronic device, and oriented such that the transmit side of the optical sensing system emits light through the display itself to illuminate an object before the display. Such a construction has several advantages including providing more area for the display, reducing the number of optical apertures required to accommodate sensors of the electronic device, reducing manufacturing complexity for displays, and so on.

However, such a construction also introduces several challenges. In particular, a display stack of an electronic device includes multiple layers, each exhibiting different optical properties, different refractive indices, and so on.

As a result of this layered structure, if a light source of a transmit side of an optical sensing system is positioned behind the display stack, light emitted from the light source must traverse each layer, and each optical interface/boundary, before exiting the display to propagate into free space. Phrased in another manner, the light emitted from the light source will be reflected, refracted, diffused, absorbed, or otherwise perturbed by each layer of the display stack in a largely unpredictable manner that can change from display stack to display stack, from manufacturer to manufacturer, and/or by temperature.

These internal reflections (and diffractions, refractions, and the like) may be received at the receive side of an optical sensing system as noise. This noise, as noted above, is typically referred to as “crosstalk” and can significantly reduce signal-to-noise ratios (more broadly, performance) of the optical sensing system.

Despite the foregoing challenges, display stacks also exhibit at least some birefringence and/or one or more other wavelength-dependent and/or polarization-dependent optical properties. In a more simple and non-limiting phrasing, any given display stack is likely to exhibit at least some wavelength and polarization dependence in respect of how much light is transmitted through the display (in both directions) and how much light is reflected and/or diffracted internally as crosstalk.

Embodiments described herein can leverage these fundamental wavelength and polarization dependent behaviors of display stacks by polarizing light output from a laser light source of an optical sensing system at a particular orientation, before that light propagates through the display stack, in order to decrease crosstalk and/or increase the portion of light emitted that propagates into free space.

For example, in some embodiments, a display can be analyzed to determine which polarization orientation(s) at a specific test wavelength are associated with lowest crosstalk and/or greatest signal (e.g., the highest signal-to-noise ratio). Once one or more suitable polarizations are identified, a single polarization orientation (e.g., a polarization filter) may be selected and positioned over the transmit side of the optical sensing system.

The foregoing described embodiments can serve to reduce crosstalk and/or increase signal, at the expense of manufacturing complexity. For example, it may be unreasonable to determine an optimal orientation for every manufactured display stack and to configure an appropriate optical sensing system therefor. Furthermore, positioning a polarizing filter of any orientation over a laser light source can result in significantly reduced optical power output.

Compounding the foregoing challenges is that laser elements are temperature sensitive devices that exhibit temperature dependent output. For example, due to thermal expansion of resonant cavities and other effects, laser elements typically output different wavelengths of light at different temperatures. Because of this, any selected display-specific polarization may not be appropriate to minimize crosstalk at all wavelengths. In another phrasing, the optimal polarization orientation to reduce crosstalk is, itself, wavelength dependent. Thus, even if an optimal polarization orientation could be reliably determined for a given display (at a given wavelength), crosstalk will still be temperature dependent and the optical sensing system will perform differently at different temperatures.

To account for these and other challenges associated with behind-display optical sensing across a wide range of temperatures, an optical sensing system as described herein is configured to leverage orthogonally-oriented pairs of polarization-locked laser light sources to exploit the polarization and wavelength dependence of a display stack in order to reduce crosstalk magnitude variation across a wide range of temperatures. As a result of architectures described herein, a behind-display optical proximity sensing system can exhibit more consistent performance through temperature changes.

More simply, the embodiments described here include at least two polarization-locked laser elements oriented orthogonally in respect of each other. In this configuration, at least one of the two laser light sources is within, at worst, forty-five degrees of an optimal polarization to reduce crosstalk and/or increase through-display signal at substantially all possible wavelengths of light emitted by the laser light sources. In this manner, if a wavelength output by the laser light sources changes (e.g., as a result of a temperature change), at least one of the two orientations of laser light can approximate or approach the optimal polarization for that particular wavelength.

Accordingly, for embodiments described herein, through-display signal magnitude and crosstalk magnitude are stabilized (e.g., less variable) across a wide array of wavelengths, which in turn corresponds to an increase in temperature independence for the optical sensing system itself. Thus, embodiments can be configured for a wider variety of applications. For example, as noted above, an optical sensing system can be configured for use as a proximity sensor for a mobile or portable electronic device. Other applications include, but are not limited to: light meters; light color sensors; proximity sensors; dot projectors; rangefinders; infrared image capture systems; ultraviolet image capture systems; direct time-of-flight depth sensors; indirect time-of-flight depth sensors; and so on.

Some embodiments include an electronic device that includes a display, such as a micro-scale light emitting diode display (“microLED”) or an organic light emitting diode display (“OLED”). Other display technologies include liquid crystal displays, quantum dot displays, and others.

In typical embodiments, an optical sensing system is configured to operate in the infrared wavelength band and is positioned on or coupled to a rear surface of, and/or integrated within, an active display area of the display of the electronic device. More specifically, as used herein the phrase “rear surface” of an active display area of a display refers to a surface of a display opposite a surface from which light is emitted by that display, which is referred to herein as the “front surface” of the display.

As a result of this construction, an optical sensing system can illuminate objects that are nearby the display of the electronic device, such as a user, to determine whether that user is nearby the display. The electronic device can utilize information received from the optical sensing system to perform any suitable task or operation or sets thereof. Examples include, but are not limited to: disabling or reducing a brightness of a display of the electronic device in response to receiving information from the optical sensing system that an object is closer than a threshold distance to the electronic device; enabling or increasing a brightness of a display of the electronic device in response to receiving information from the optical sensing system that an object is farther than a threshold distance to the electronic device; enabling or disabling a touch or force input system of the electronic device in response to receiving information from the optical sensing system that an object is nearby (e.g., a distance satisfying a threshold or within a threshold range) the electronic device; and so on.

In this manner, more generally and broadly, embodiments described herein facilitate through-display detection (and/or imaging) of an object nearby the front surface of a display of an electronic device.

As introduced above, an optical sensing system includes a module enclosure divided into two portions, referred to herein as a transmitter side and a receiver side. The transmitter side and the receiver side are each defined by a respective one internal volume defining a respective imaging aperture at one end. Within the transmitter side internal volume, or more simply the transmitter internal volume, is disposed a polarization-locked laser element.

In one example, the polarization-locked laser element is a vertical-cavity surface-emitting laser (“VCSEL”) or an array thereof that includes a polarizing grating within the laser cavity and/or over an output aperture of the VCSEL itself. As a result of this construction, light resonating with the VCSEL cavity locks to a particular polarization before being emitted as polarized, coherent light. In some examples, a polarization-locked VCSEL (or “PL-VCSEL”) can be configured to emit s-polarized light or p-polarized light.

A VCSEL is one example laser topology that can include optical elements, cavity layers, or other surface treatments or features that lock to a particular polarization. In other examples, a Fabry-Pérot laser diode, distributed feedback laser, an edge-emitting laser, a horizontal cavity surface-emitting laser, resonant cavity light-emitting diode, and so on (or arrays thereof) may be used. For simplicity of description and illustration the embodiments that follow reference optical sensing systems that include PL-VCSELs, but this may not be required of all embodiments.

The polarization-locked laser element pair may be formed as VCSELs on the same substrate. In other cases, the polarization-locked laser elements may be formed on separate dies that are secured to a common substate in a relative orthogonal relationship. In some embodiments, a single die may include multiple polarization-locked laser elements, each polarized in the same orientation. In this example, two different but identically manufactured dies can be placed on a single substrate in an orthogonal orientation. Regardless of implemented architecture, an optical sensing system as described herein can include a polarization-locked laser element pair within a transmitter-side internal volume. The pair can be configured to operate simultaneously, can be separately modulated, or may be time multiplexed. Many possible drive schemas and techniques are possible.

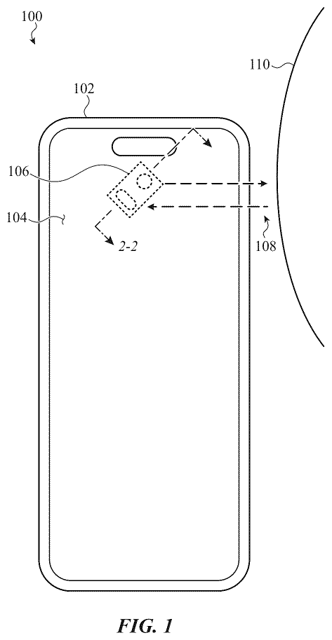

These foregoing and other embodiments are discussed below with reference to FIGS. 1-6. However, those skilled in the art will readily appreciate that the detailed description given herein with respect to these figures is for explanation only and should not be construed as limiting.

FIG. 1 depicts an electronic device 100, including a housing 102 that encloses a stack of multiple layers, referred to as a “display stack.” The display stack cooperates to define a digital display configured to render visual content to convey information to, to solicit touch or force input from, and/or to provide entertainment to a user of the electronic device 100.

The display stack can include layers or elements such as, in no particular order: a touch input layer; a force input layer; a haptic output layer; a thin-film transistor layer; an anode layer; a cathode layer; an organic layer; an encapsulation layer; a reflector layer; a stiffening layer; an injection layer; a transport layer; a polarizer layer; an anti-reflective layer; a liquid crystal layer; a backlight layer; one or more adhesive layers; a compressible layer; an ink layer; a mask layer; and so on.

For simplicity of description, the embodiments that follow reference a display stack implemented with an organic light emitting diode display technology and can include, among other layers: a reflective backing layer; a thin-film transistor layer; an encapsulation layer; and an emitting layer. It is appreciated, however, that this is merely one illustrative example implementation and that other displays and display stacks can be implemented with other display technologies, or combinations thereof. An example of another display technology that can be used with display stacks and/or displays such as described herein is a micro light emitting diode display.

The display stack also typically includes an input sensor (such as a force input sensor and/or a touch input sensor) to detect one or more characteristics of a user's physical interaction with an active display area 104 defined by the display stack of the display of the electronic device 100.

The active display area 104 is typically characterized by an arrangement of individually-controllable, physically-separated, and addressable pixels or subpixels distributed at one or more pixel densities and in one or more pixel or subpixel distribution patterns. In a more general phrasing, the active display area 104 is typically characterized by an arrangement of individually-addressable discrete light-emitting regions or areas that are physically separated from adjacent or other nearby light-emitting regions.

In many embodiments, the light-emitting regions defining the active display area 104 are disposed onto, or formed onto, a transparent substrate that may be flexible or rigid. Example materials that can form a transparent substrate, such as described herein can include polyethylene terephthalate and/or glass. In other cases, a partially opaque substrate can be used; in such embodiments, at least a portion of the substrate between the pixels defined thereon may be partially or entirely optically transparent.

In addition, example input characteristics that can be detected by an input sensor of the electronic device 100—which can be disposed above or below a display stack, or, in other cases, can be integrated with it—can include, but are not limited to: touch location; force input location; touch gesture path, length, duration, and/or shape; force gesture path, length, duration, and/or shape; magnitude of force input; number of simultaneous force inputs; number of simultaneous touch inputs; and so on.

As a result of these constructions, a user of the electronic device 100 may be encouraged to interact with content shown in the active display area 104 of the display by physically touching and/or applying a force with the user's finger to the input surface above an arbitrary or specific region of the active display area 104.

In these embodiments, as with other embodiments described herein, the display stack is additionally configured to facilitate through-display proximity sensing. In particular, the display stack further includes and/or is coupled to an optical sensing system 106 positioned relative to a rear surface of the display stack. As a result of this construction, the optical sensing system 106 can be operated by the electronic device 100 to determine whether an object is proximate to the active display area 104 of the electronic device 100.

More specifically, in one example, the display stack defines an optical sensing aperture or an array of discrete and separated optical sensing apertures (not shown) through a backing layer or other opaque layer defining a rear surface of the display stack, thereby permitting light to travel through the display stack from the rear surface to the front surface (and vice versa) between two or more organic light emitting diode subpixels or pixels (herein, “inter-pixel” regions).

In some cases, the optical sensing aperture takes a generally rectangular shape and is disposed on a lower region of the active display area 104, but this may not be required. The optical sensing system 106 can, in many embodiments, be angled with respect to a central axis of the electronic device 100. In the illustrated embodiment, the optical sensing system 106 is angled approximately forty five degrees relative to a vertical central axis of the electronic device 100, but this is not required of all embodiments.

In other cases, the optical sensing aperture takes a circular or oval shape and is disposed in a central region of the active display area 104. In some embodiments, the backing layer may be omitted entirely; the optical sensing aperture may take the same size and shape as the active display area 104.

In some embodiments, multiple optical sensing apertures with different shapes are separated and supported by opaque and light absorbing backing layer or additional optical/mechanical structure.

In these embodiments, the optical sensing system 106 is positioned at least partially relative to (e.g., below) the optical sensing aperture in order to collect and quantify light directed through the inter-pixel regions of the display stack, traveling through the display stack in a direction substantially opposite to a direction of travel of light emitted by the display stack.

More specifically, the optical sensing system 106 is configured to emit and capture light incident to the front surface of the display that passes through an inter-pixel region of the display stack.

In some embodiments, the optical sensing system 106 can be configured to operate with the display such that the display emits light in order to illuminate an object in contact with the front surface of the display (or an outer protective layer covering the front surface of the display). In these examples, light emitted from one or more light-emitting regions of the display (e.g., pixels) can be reflected from the surface of the object and, thereafter, can travel through the display stack, through an optical sensing aperture, and can be collected/absorbed by at least one photosensitive area or region (e.g., a photodiode) of the optical sensing system 106.

In particular, as noted with respect to other embodiments described herein, the optical sensing system 106 may be configured to emit light through the optical sensing aperture and to receive light from the optical sensing aperture. The light 108 emitted and received by the optical sensing system 106 may be used to detect the presence and/or proximity and/or range of an object 110, which may be a user of the electronic device 100.

These foregoing embodiments depicted in FIG. 1 and the various alternatives thereof and variations thereto are presented, generally, for purposes of explanation, and to facilitate an understanding of various configurations and constructions of a system, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

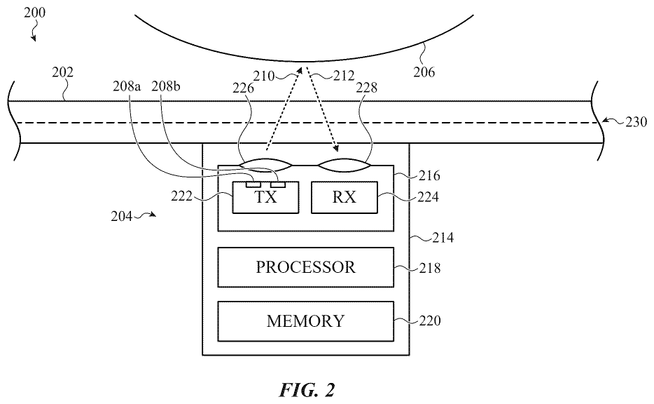

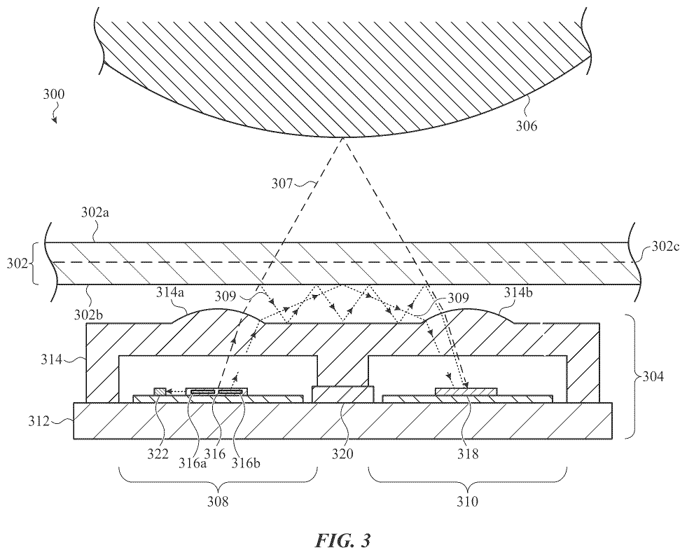

FIGS. 2-3 depict example cross-sectional views of an optical sensing system, such as described herein. In particular, FIG. 2 depicts a simplified schematic representation of a cross-section view through line 2-2 of FIG. 1.

In other examples, as noted above, crosstalk interference may further contribute to poor performance of a conventional proximity sensor. For example, as noted with respect to FIG. 1, an optical sensing system as described herein is, in many embodiments, disposed below an active display area of a display of an electronic device.

These and other examples are presented below with reference to FIGS. 2-3. In particular, FIG. 2 depicts a cross-section view, taken through line 2-2, of the optical sensing system described in reference to FIG. 1.

In particular, FIG. 2 illustrates an electronic device 200 that includes a housing that defines an interior volume to enclose and support a display 202. Within the interior volume of the housing, behind the display 202, is an optical sensing system 204. The optical sensing system 204 can be used to detect proximity of an object 206, which is a user of the electronic device 200. For example, if the electronic device 200 is a portable electronic device such as a cellular phone, the optical sensing system 204 can be leveraged as a proximity sensor that determines when and/or whether the cellular phone should disable a capacitive touch screen (e.g., when a user of the cellular phone holds the cellular phone nearby the user's head/ear).

As with other embodiments described herein, the optical sensing system 204 can be configured with a pair of polarization-locked laser light elements, the laser elements 208a, 208b. The laser elements 208a, 208b may be VCSEL elements that are polarization-locked (PL-VCSELs) and oriented orthogonal/perpendicular to one another. The laser elements 208a, 208b can include one or more layers or optical elements that encourage light resonating within the laser cavity to lock to a particular polarization (e.g., an s-polarization or a p-polarization).

The laser elements 208a, 208b emit light 210 through the display 202. The light 210 exits the housing of the electronic device 200 to illuminate a field of view normal to and/or extending from an external surface of the display 202.

In this configuration, when the object 206 enters the field of view, at least a portion of the light 210 is reflected from an external surface of the object 206. A portion of the reflected light 212 may be redirected toward the outer surface of the display 202. At least a portion of that reflected light can traverse through the display 202 and can illuminate the optical sensing system 204, which may excite a photodiode or other optically sensitive element, structure, or material. The optical sensing system 204 can leverage this excitation to determine whether the object 206 is proximate to, or within at least a threshold distance of, the external surface of the electronic device 200.

The optical sensing system 204 is enclosed within a module housing 214 that encloses and supports at least a portion of the internal components thereof. As with other embodiments described herein, the module housing 214 defines a transmitter side and a receiver side. In particular, the module housing 214 defines a set of internal volumes 216 that includes a transmitter internal volume and a receiver internal volume that are optically isolated from one another to minimize crosstalk therebetween.

The module housing 214 can also optionally be configured to enclose and support an Application-Specific Integrated Circuit (ASIC) that includes at least a processor 218 and a memory 220. In other cases, the processor 218 and the memory 220 can be formed on separate dies and/or within separate integrated circuit packages. The processor 218 can be a general purpose processor configured to access the memory 220 to obtain executable instructions, computer code, and/or other digital assets that can be leveraged by the processor 218 to instantiate an application, firmware, or other process or instance of software.

In other cases, the processor 218 may be a purpose-configured processor configured to receive digital input(s) and to provide digital and/or analog output(s). As such, as described herein, the term “processor” refers to any software and/or hardware-implemented data processing device or circuit physically and/or structurally configured to instantiate one or more classes or objects that are purpose-configured to perform specific transformations of data including operations represented as code and/or instructions included in a program that can be stored within, and accessed from, a memory (such as the memory 220). This term is meant to encompass a single processor or processing unit, multiple processors, multiple processing units, analog or digital circuits, or other suitably configured computing element or combination of elements.

Regardless of configuration, the processor 218 can be operationally and/or communicably coupled to the memory 220 and/or to other electronic components of the electronic device 200 or the optical sensing system 204. For example, the processor 218 can be operably coupled to a transmitter module 222 and a receiver module 224. As a result of these constructions, the processor 218 can be leveraged to perform one or more calibration operations to regulate performance of the transmitter module 222 or the receiver module 224. Example calibrations can include, but may not be limited to: thermal calibration of a polarization-locked laser element of the transmitter module 222 (e.g., the laser elements 208a, 208b); thermal calibration of a photosensitive element or photosensor of the receiver module 224; crosstalk calibration of an output of the receiver module 224; optical calibration of the transmitter module 222; and so on.

The memory 220 of the ASIC can be used, as noted above, to store assets that can be leveraged by the processor 218. In certain further embodiments, the optical sensing system 204 can further include one or more lenses, such as a transmitter-side lens 226 and a receiver-side lens 228.

As a result of the depicted construction, the optical sensing system 204 can be operated by the processor 218 to cause light to be emitted by the transmitter module 222, pass through the display 202 (and, in particular, between inter-pixel regions of a pixel layer 230 of the display 202), reflect from the object 206, pass through the display 202 and the pixel layer 230 again, and enter the receiver module 224.

FIG. 3 depicts another cross-section view of an optical sensing system, such as described herein. FIG. 3 presents a more detailed view of the example system diagram shown in FIG. 2. In particular, FIG. 3 depicts an electronic device 300 that, as with other embodiments described herein, includes a housing that defines an interior volume. Within the interior volume defined by the housing is disposed a display 302 that is defined, at least in part, by a stacking or layering of functional and structural layers in a display stack.

The display stack of the display 302 defines an outer surface 302a and an interior surface 302b. An active display area of the display 302 is defined by an arrangement of pixels in turn defined in a pixel layer 302c. The pixel layer 302c is at least partially optically transparent between pixels or subpixels of the layer so that light emitted from an optical sensing system 304 may traverse the active display area and exit the electronic device 300 through the outer surface 302a to illuminate an object 306.

The optical sensing system 304 includes a transmitter side 308 and a receiver side 310. The transmitter side 308 and the receiver side 310 can be formed onto a rigid substrate 312. The rigid substrate 312 can serve as a support and/or platform to couple to a module housing 314 that optically separates or isolates the transmitter side 308 from the receiver side 310. The module housing 314 in some embodiments can define one or more optical elements such as an optical element 314a, or an optical element 314b. In the illustrated embodiment, the optical elements 314a, 314b may be lenses, but it is appreciated that this is merely one example; other optical elements, filter elements, gratings, antireflective coatings and the like can be used in other embodiments.

The transmitter side 308 includes an orthogonally-oriented pair of polarization-locked laser elements 316, that includes a first PL-VCSEL and a second PL-VCSEL labeled as the PL-VCSELs 316a, 316b.

The orthogonally-oriented pair of polarization-locked laser elements 316 can be any suitable light emitting element, but in many embodiments, the orthogonally-oriented pair of polarization-locked laser elements 316 are implemented as VCSELs constructed with one or more polarization filters or optical elements to encourage locking into a particular polarization. The VCSELs may be configured to emit infrared light.

The orthogonally-oriented pair of polarization-locked laser elements 316 can be implemented as a single element or as an array of discrete elements, on one or more dies. Further, although not required for all embodiments, the orthogonally-oriented pair of polarization-locked laser elements 316 may be a Class 1 laser as defined by the American National Standards Association.

The orthogonally-oriented pair of polarization-locked laser elements 316 is configured to emit light at a particular wavelength, bandwidth, or power through the display 302 to illuminate a field of view extending from the outer surface 302a. When the field of view is interrupted by the object 306, at least a portion of the emitted light reflects from the object 306 and returns to the optical sensing system 304 by traversing, once again, through the display 302. In particular, the reflected emitted light can illuminate a photosensor 318 within the receiver side 310.

The photosensor 318 can be any suitable photosensitive element or structure. For simplicity of description, the embodiments that follow reference a semiconductor photodiode (hereinafter, a “photodiode”). The photosensitive area of this example photodiode is responsive to light in the spectral range emitted by the orthogonally-oriented pair of polarization-locked laser elements 316. As with the orthogonally-oriented pair of polarization-locked laser elements 316, the photosensor 318 of the receiver side 310 can be implemented as a single element or as an array of elements.

Both the photosensor 318 and the orthogonally-oriented pair of polarization-locked laser elements 316 are operably coupled to an ASIC 320. The ASIC 320 can be configured to drive the orthogonally-oriented pair of polarization-locked laser elements 316 with a current, a modulated current, or any other suitable current-controlled, power-controlled, or voltage-controlled signal.

In many examples, the ASIC 320 is configured to drive the orthogonally-oriented pair of polarization-locked laser elements 316 with a current signal configured to cause the orthogonally-oriented pair of polarization-locked laser elements 316 to emit modulated infrared light toward the object 306. In addition, the ASIC 320 can be configured to receive a current, voltage, or power signal from the photosensor 318.

In some embodiments, the optical sensing system 304 can also include a photodiode 322 within the transmitter side 308. The photodiode 322 can be used by the ASIC 320 to calibrate an operation of the orthogonally-oriented pair of polarization-locked laser elements 316. In further embodiments, a calibration photodiode can also be included in the receiver side 310 and may be positioned within the receiver-side internal volume, outside of the module housing, or elsewhere.

When the orthogonally-oriented pair of polarization-locked laser elements 316 are operated to emit light toward the object 306, some of the light emitted by the orthogonally-oriented pair of polarization-locked laser elements 316 may be measured by the photosensor 318 without first interacting with the object 306 (e.g., as crosstalk). In FIG. 3, light path 307 represents a path by which light emitted by the orthogonally-oriented pair of polarization-locked laser elements 316 may be emitted through the pixel layer 302c (e.g., via an inter-pixel region of the pixel layer 302c), interact with the object 306, return through the pixel layer 302c (e.g., via another inter-pixel region of the pixel layer 302c), and be measured by the photosensor 318. Conversely, light paths 309 represent example crosstalk paths in which light emitted by the orthogonally-oriented pair of polarization-locked laser elements 316 may be redirected by the display 302 (e.g., via reflection, diffraction, or the like), such that the light is measured by the photosensor 318 without first exiting the electronic device 300. Accordingly, by increasing the relative amount of light that passes through the display 302, the impact of these crosstalk paths may be reduced.

These foregoing embodiments depicted in FIGS. 2-3 and the various alternatives thereof and variations thereto are presented, generally, for purposes of explanation, and to facilitate an understanding of various configurations and constructions of a system, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

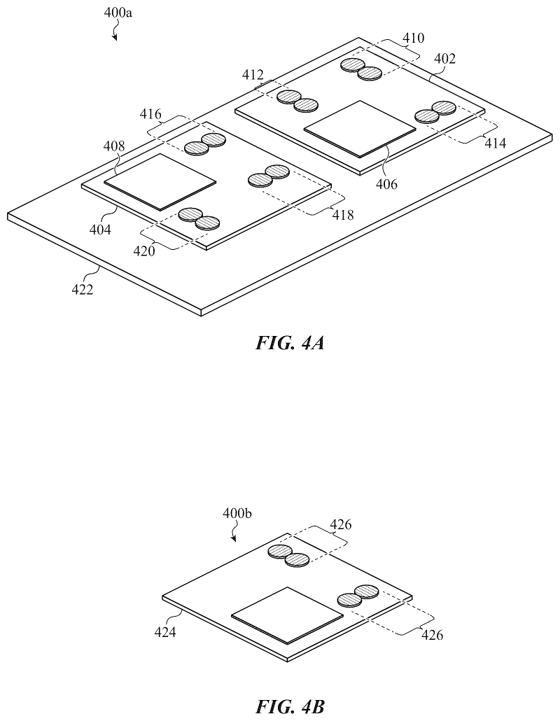

For example, FIG. 4A depicts an example pair of orthogonally-oriented dies, each including at least one polarization-locked VCSEL elements. The pair 400a includes two dies, the first die 402 and the second die 404. Each of the dies may be manufactured in a single process, later singulated, and placed at an orthogonal orientation relative to one another and affixed to a common substrate (not shown).

The manufacturing process selected to construct the dies may vary from embodiment to embodiment. However, as noted above, a VCSEL or other laser light source as described herein is configured for polarization-locked operation. More specifically, each VCSEL formed onto each respective die can include one or more optical gratings, optical elements, filters, or the like, to encourage locking to a particular polarization before exiting a resonant cavity of the laser.

For example, a single substrate can be used to manufacture a plurality of dies such as described herein. One or more semiconductor manufacturing processes (e.g., lithography, etching, layer deposition, annealing, dopant implantation, and the like) can be performed across the entire substrate as a singular body to define one or more circuits, one or more reflectors (e.g., distributed Bragg reflectors), one or more apertures, one or more active layers, one or more gratings, and the like. In addition, the substrate can have formed thereon one or more polarizing layers or polarization filters that encourage locking within the resonant cavity. In these examples, each VCSEL or laser element defined on the substrate can be configured to emit coherent polarized light, oriented in a common polarization direction. Upon completion of manufacturing operations, the substrate can be singulated and multiple individual dies can be paired together, and aligned orthogonally, as shown in FIG. 4 in respect of the relative orientations of the first die 402 and the second die 404.

Each of the dies can include an asymmetrical arrangement of components and parts, although this is not required of all embodiments. The asymmetric arrangement can eliminate any need for alignment fiducials to be separately manufactured or defined in either die.

Each respective die can be defined by a substrate onto which is formed and/or otherwise defined or placed one or more circuits, traces, or electronic elements such as the first controller 406 or the second controller 408. The controllers can be configured, at least in part, to drive VCSEL elements disposed on each respective die. More specifically, the controllers can be configured to receive as input one or more digital or analog signals and to output in response a current corresponding to the input to stimulate one or more VCSEL elements to emit coherent, polarized light.

In the illustrated embodiment, each of the first die 402 and the second die 404 can be formed with six individual laser elements, but this is not required of all embodiments and in other embodiments a greater or fewer number may be used. In particular, the first die 402 includes the polarization-locked VCSEL elements 410, 412, 414 with a polarization oriented that is the same orientation as the polarization-locked VCSEL elements 416, 418, 420 formed onto the second die 404. As a result of the same manufacturing, and same orientation, physical rotation of the die on which the polarization-locked VCSEL elements 416, 418, 420 is formed serves to orient light emitted from those VCSELs perpendicular to the light emitted from the VCSELs of the first die 402. In these embodiments, the first die 402 and the second die 404 can be coupled to a common substrate 422.

In some cases, more than two orientations and/or non orthogonal orientations are possible. For example, a first set of polarization-locked laser elements can be oriented 30 degrees off from a second set of polarization-locked laser elements. In other cases, a set of polarization-locked laser elements can be defined onto a die, each of which is associated with a different orientation (e.g., 0 degrees, 30 degrees, 45 degrees, 60 degrees, 90 degrees, and so on).

In some cases, all polarization-locked laser elements can be driven at the same time. In other cases, individual VCSELs can be independently driven. Some of the VCSELs may be driven at the same current and/or frequency, whereas in other embodiments, different VCSELs of the same die or a different die can be drive with different input current to output different intensities or wavelengths of light. Output may be modulated in any suitable way.

Further, it may be appreciated that in some embodiments, a single die can include multiple laser elements with different polarization-locked orientations. FIG. 4B depicts such an example in which a pair 400b of polarization-locked laser elements are formed onto a single die 424. In particular, the single die 424 includes one or more polarization-locked VCSEL elements 426 configured to emit polarized light in a first orientation (e.g., s-polarization) and a second set of polarization-locked VCSEL elements 426 configured to emit polarized light in a second orientation orthogonal to the first orientation.

In some embodiments, a single VCSEL element in each orientation may be suitable. In other embodiments, more than two VCSEL elements can be formed and configured to emit similarly-oriented or identically-oriented polarized light.

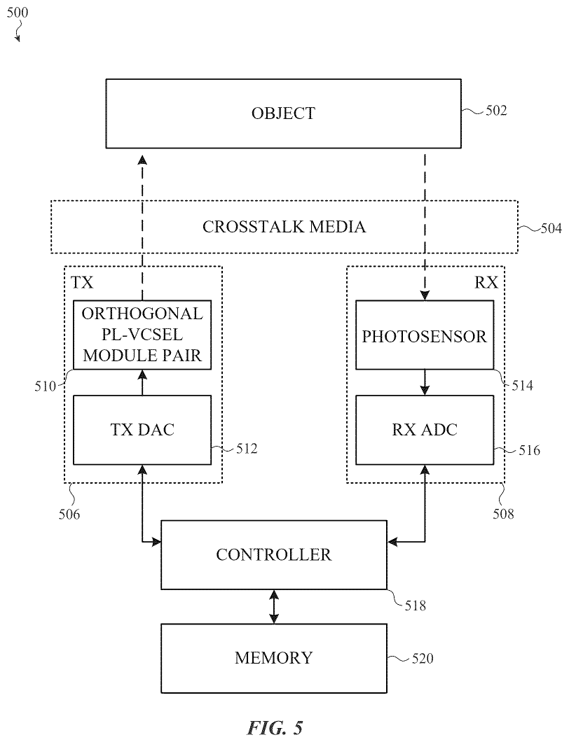

FIG. 5 depicts a simplified system diagram of an optical sensing system, such as described herein. The optical sensing system 500 is configured to detect presence of and/or distance to an object 502, through an arbitrary crosstalk media 504. An example of a crosstalk media is a display stack of an electronic device (see, e.g., FIGS. 2-3). In other examples, other crosstalk media may be present.

The optical sensing system 500 includes a transmitter side 506 and a receiver side 508. The transmitter side 506 includes a light emitting element, shown as the pair of polarization-locked VCSEL elements 510. The pair of polarization-locked VCSEL elements 510 receives an analog power or current signal from a digital-to-analog converter 512. In this manner, a digital current value received by the digital-to-analog converter 512 is converted to an analog current which, in turn, causes one or more of the pair of polarization-locked VCSEL elements 510 to emit light, such as modulated infrared light.

The receiver side 508 that includes a photosensor 514. The photodiode 514 is configured to receive light emitted from the pair of polarization-locked VCSEL elements 510 after interacting with the object 502. Depending on the configuration of the optical sensing system 500, the photosensor 514 may also measure light (e.g., as crosstalk) returned from the crosstalk media 504 without interacting with the object 502. The receiver side 508 may include an analog-to-digital converter 516, which may convert an analog output signal generated by the photosensor 514 into a digital output signal.

The optical sensing system 500 can also include a controller 518 and a memory 520 that can cooperate to perform, coordinate, or supervise one or more operations of the optical sensing system 500.

These foregoing embodiments depicted in FIG. 5 and the various alternatives thereof and variations thereto are presented, generally, for purposes of explanation, and to facilitate an understanding of various configurations and constructions of a system, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

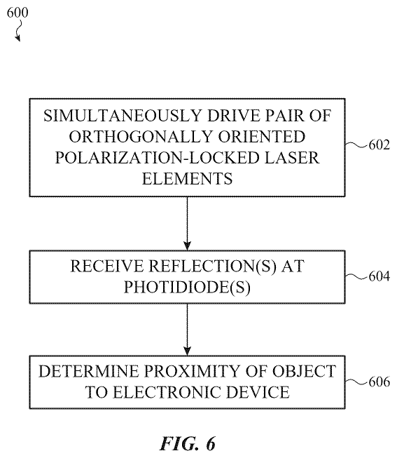

FIG. 6 depicts a flow chart corresponding to a method of operating an optical sensing system as described herein. In this example method, a pair of orthogonally oriented polarization-locked laser element can be simultaneously drive (e.g., operation 602). A single photodiode or an array of photodiodes can be used—without preference to either polarization and without including a respective polarization filter thereover—to receive reflections associated with the light emitted by the polarization-locked laser elements (e.g., operation 604). Finally, at operation 606, a controller coupled to the laser elements and/or the photodiode can be used to determine whether an object is within a threshold distance of the optical sensing system and, in some cases, a distance at which that object exists.

This method is merely one of many methods of operating an optical sensing system as described herein. For example, in some cases, a first orientation of a phase-locked laser element can be drive at a different time than a second orientation of a different phase-locked laser element. In some cases, more than just to orientations can be included, and driven at different times. For example, in some embodiments, an array of different orientations of polarization can be driven one at a time to determine which orientation is associated with highest signal to noise ratios.

One may appreciate that, although many embodiments are disclosed above, the operations and steps presented with respect to methods and techniques described herein are meant as exemplary and accordingly are not exhaustive. One may further appreciate that alternate step order or fewer or additional operations may be required or desired for particular embodiments.

As used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

As used herein, the term “abutting” means that two elements share a common boundary or otherwise contact one another, while the term “adjacent” means that two elements are near one another and may (or may not) contact one another. Thus, elements that are abutting are also adjacent, although the reverse is not necessarily true. Two elements that are “coupled to” one another may be permanently or removably physically coupled to one another and/or operationally or functionally coupled to one another.

Although the disclosure above is described in terms of various exemplary embodiments and implementations, it should be understood that the various features, aspects, and functionality described in one or more of the individual embodiments are not limited in their applicability to the particular embodiment with which they are described, but instead can be applied, alone or in various combinations, to one or more embodiments, whether or not such embodiments are described and whether or not such features are presented as being a part of a described embodiment. Thus, the breadth and scope of this description should not be limited by any of the above-described exemplary embodiments but is instead defined by the claims herein presented. For example, any stationary or portable electronic device can include an optical sensing system, such as described herein. Example electronic devices include, but are not limited to: mobile phone devices; tablet devices; laptop devices; desktop computers; computing accessories; peripheral input devices; home or business networking devices; aerial, marine, submarine, or terrestrial vehicle control devices or networking devices; mobile entertainment devices; augmented reality devices; virtual reality devices; industrial control devices; digital wallet devices; home or business security devices; wearable devices; health or medical devices; implantable devices; clothing-embedded devices; fashion accessory devices; home or industrial appliances; media appliances; and so on.

What is claimed is:

1. An optical sensing system comprising:
a transmitter side comprising:
a first die comprising a first polarization-locked vertical cavity surface emitting laser (VCSEL) element configured to emit polarized light with a first orientation; and
a second die comprising a second polarization-locked VCSEL element configured to emit polarized light with a second orientation orthogonal to the first orientation; and
a receiver side comprising a photodiode configured to receive a reflection of light emitted from either the first polarization-locked VCSEL element or the second polarization-locked VCSEL element.

2. The optical sensing system of claim 1, comprising a module enclosure enclosing the transmitter side and the receiver side, the module enclosure defining:
a first aperture through which the first polarization-locked VCSEL element and the second polarization-locked VCSEL element are configured to emit light; and
a second aperture through which the photodiode is configured to receive light.

3. The optical sensing system of claim 2, wherein the module enclosure defines a first internal volume in which the first die and the second die are disposed and a second internal volume in which the photodiode is disposed.

4. The optical sensing system of claim 3, wherein the first internal volume and the second internal volume are optically isolated from one another.

5. The optical sensing system of claim 2, wherein the module enclosure is configured to couple to an interior surface of a display stack of an electronic device.

6. The optical sensing system of claim 5, wherein the module enclosure is oriented at an angle with respect to a centerline of an active display area.

7. The optical sensing system of claim 5, wherein the first polarization-locked VCSEL element is configured to emit light through an inter-pixel region of the display stack.

8. The optical sensing system of claim 5, wherein the transmitter side is positioned to emit light through the display stack below the active display area defined by the display stack.

9. The optical sensing system of claim 1, wherein both the first polarization-locked VCSEL element and the second polarization-locked VCSEL element emit infrared light.

10. The optical sensing system of claim 1, wherein the photodiode is configured to detect infrared light.

11. The optical sensing system of claim 1, wherein the first die comprises:
an array of VCSEL elements comprising the first polarization-locked VCSEL element, each element of the array of VCSEL elements configured to emit light polarized with the first orientation.

12. The optical sensing system of claim 11, wherein the second die comprises:
an array of VCSEL elements comprising the second polarization-locked VCSEL element, each element of the array of VCSEL elements configured to emit light polarized with the second orientation.

13. The optical sensing system of claim 1, wherein:
the first die and the second die have a same die configuration; and
the second die is oriented orthogonally in respect of the first die.

14. The optical sensing system of claim 1, wherein the first die comprises a controller configured to drive the first polarization-locked VCSEL element with a current.

15. The optical sensing system of claim 14, wherein:
the controller is a first controller;
the current is a first current; and
the second die comprises a second controller configured to drive the second polarization-locked VCSEL element with a second current.

16. The optical sensing system of claim 1, wherein the first die and the second die are coupled to a substrate.

17. A portable electronic device comprising:
a housing;
a display within the housing defining:
an interior surface;
an active display area; and
an exterior surface; and
an optical sensing system disposed on the interior surface, and oriented to emit light through the active display area to propagate from the exterior surface to illuminate an object within a field of view of the portable electronic device, the optical sensing system comprising:
a first polarization-locked laser element configured to emit polarized light;
a second polarization-locked laser element configured to emit polarized light, the second polarization-locked laser element oriented orthogonally with respect to the first polarization-locked laser element; and
a photodiode configured to receive a reflection of light emitted from either the first polarization-locked laser element or the second polarization-locked laser element to determine whether an object is present within the field of view.

18. The portable electronic device of claim 17, wherein the optical sensing system is configured to determine a distance to the object.

19. The portable electronic device of claim 17 wherein the first polarization-locked laser element is configured such that at least a portion of the polarized light emitted by the first polarization-locked laser element is emitted through an inter-pixel region of the active display area.

20. A method of operating an optical proximity sensing system behind a display of an electronic device, the method comprising:
emitting first laser light at a first polarization orientation though an inter-pixel region of the display;
emitting second laser light at a second polarization orientation orthogonal to the first polarization orientation through the inter-pixel region of the display;
receiving, through the inter-pixel region of the display, a reflection of one or both of the first laser light or the second laser light at photodiode and in response determining that an object is present within a field of view of the electronic device.
